(19) United States
(12) Patent Application Publication
(10) Pub. No.: US 2024/0069454 A1
(43) Pub. Date: Feb. 29, 2024

(54) DATA FILTER FOR SCANNING METROLOGY

(71) Applicant: ASML NETHERLANDS B.V., Veldhoven (NL)

(72) Inventors: Cristina CARESIO, Eindhoven (NL); Tabitha Wangari KINYANJUI, Heumen (NL); Andrey Valerievich ROGACHEVSKIY, Den Bosch (NL); Bastiaan Andreas Wilhelmus Hubertus KNARREN, Nederweert-Eind (NL); Raymund CENTENO, Nijmegen (NL); Jan Arie DEN BOER, Strijen (NL); Viktor TROGRLIC, Eindhoven (NL)

(73) Assignee: ASML NETHERLANDS B.V., Veldhoven (NL)

(21) Appl. No.: 18/280,266

(22) PCT Filed: Feb. 21, 2022
(86) PCT No.: PCT/EP2022/054191

§ 371 Date: Sep. 4, 2023

(30) Foreign Application Priority Data
Mar. 4, 2021 (EP) 21160810.4
Jul. 29, 2021 (EP) 21188528.0

(51) Int. Cl. G03F 9/00

(52) U.S. Cl. CPC G03F 9/7034; G03F 9/7092

(57) ABSTRACT

A method of processing a data set including equispaced and/or non-equispaced data samples is disclosed. The method includes filtering of the data, wherein a kernel defined by a probability density function is convoluted over samples in the data set to perform a weighted average of the samples at a plurality of positions across the data set, and wherein a first order regression is applied to the filtered data to provide a processed data output.

### CROSS-REFERENCE TO RELATED APPLICATIONS

This application claims priority of EP application 21160810.4 which was filed on 4 Mar., 2021, and EP application 21188528.0 which was filed on 29 Jul., 2021, and which are incorporated herein in their entirety by reference.

### FIELD

The present invention relates to a data filter, and particularly to a filter for use with scanning metrology data.

### BACKGROUND

Although not exclusively for such applications, embodiments of the invention as disclosed herein are discussed in relation to a lithographic apparatus. A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In lithographic processes, it is frequently desirable to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field.

A topography measurement system, level sensor or height sensor, and which may be integrated in the lithographic apparatus, is arranged to measure a topography of a top surface of a substrate (or wafer). A map of the topography of the substrate, also referred to as a height map, may be generated from these measurements indicating a height of the substrate as a function of the position on the substrate. This height map (wafer Z-map or WZM) of the substrate may, for example, subsequently be used to correct the position of the substrate with respect to a projection system before or during transfer of the pattern on the substrate in order to provide an aerial image of the patterning device in a properly focused position on the substrate. It will be understood that “height” in this context refers to a dimension broadly out of the plane to the substrate (also referred to as Z-axis). Typically, the level or height sensor performs measurements at a fixed location (relative to its own optical system) and a relative movement between the substrate and the optical system of the level or height sensor results in height measurements at locations across the substrate.

In a conventional lithographic apparatus, the height map may be generated by sampling the height of the substrate at predetermined equidistant positions, e.g. positions lying on a rectangular measurement grid. Equidistant positions may also be referred to as equispaced positions. A height level sensor and the substrate may be moved with respect to each other along a trajectory, which trajectory is selected along the predetermined positions. In the conventional lithographic apparatus, the measurement samples are taken while the substrate and the height level sensor move with respect to each other at a constant velocity. Thus, the height level sensor samples the equidistant measurement positions by sampling at a constant sampling rate. It is noted that in the measuring process the substrate or the height level sensor or both may move.

U.S. Pat. No. 7,227,614 B2 discloses an improved level sensor for obtaining a Z-map, in which the sensor samples are taken even while the sensor is accelerating/decelerating. This enables the level sensor samples to be obtained more quickly. However this means that the samples acquired by the sensor are not equispaced and this has consequences for the data processing, in which the raw data must first be filtered (low-pass filter) to remove noise etc. Conventional low-pass filters have been found not to be suitable, or at least not optimal, for processing non-equispaced samples. Accordingly, it may be desirable to provide alternative data processing means to handle non-equispaced samples.

### SUMMARY

According to an aspect of the current disclosure, there is provided a method of processing a data set comprising equispaced and/or non-equispaced data samples. The method comprises filtering of the data, wherein a kernel defined by a probability density function is convoluted over samples in the data set to perform a weighted average of the samples at a plurality of positions across the data set, and wherein a first order regression is applied to the filtered data to provide a processed data output.

The filtering may comprise a tandem filter applied to the data prior to the convolution of the kernel over samples in the data set. The tandem filter may be a sample averaging filter.

The filtering may be performed in a time and/or space domain.

The non-equispaced samples may be temporally spaced and/or spatially spaced.

The data set may comprise measurements obtained from a scanning sensor. The scanning sensor may perform a scan across the surface of a wafer in a lithographic apparatus. The sensor may be a level sensor. The level sensor may scan across the surface of the wafer at a variable speed so as to accelerate and decelerate across portions of the wafer surface while obtaining sensor data, and wherein the data output is used to provide an accelerated wafer Z-map (AWZ-Map) of the level of the wafer surface.

The shape of the kernel may change in response to variations in the spacing of the data samples.

The kernel defined by a probability density function may be a Gaussian kernel. The Gaussian kernel may be a normalized Gaussian kernel having a defined area based on a sensor spot size and a sample interval, the defined area of the normalized Gaussian kernel being maintained constant for the filtering of the data set.

The filtering of the data samples may comprise low-pass filtering wherein a cut-off frequency above which data is filtered out varies according to variations in the spacing of the samples.

In some embodiments, wherein the processed output data is required for a set of predetermined spaced locations, processing of the data set may be performed only at those predetermined locations. The predetermined locations may be predetermined grid points over a scanned area. The scanned area may be a surface of a wafer in a lithographic apparatus, the sensor being a level sensor and the predetermined locations at which the data is processed being predetermined wafer grid points.

According to another aspect of the current disclosure, there is provided a method of obtaining an accelerated wafer Z-map in a lithographic apparatus. The method comprises: using a scanning level sensor to obtain a set of data samples of level measurements across a surface of the wafer; filtering the data in a time and/or space domain using a kernel defined by a probability density function that is convoluted over samples in the data set to perform a weighted average of the samples at a plurality of positions across the data set; and applying a first order regression to the filtered data to obtain a level value for each of the plurality of positions.

The set of data samples of level measurements may be filtered by a tandem filter prior to being filtered in a time and/or space domain using a kernel defined by a probability density function. The tandem filter may be a sample averaging filter.

In some embodiments a sample interval between successive samples varies and wherein the shape of the kernel changes in response to variations in the sample interval.

The kernel defined by a probability density function may be a Gaussian kernel. The Gaussian kernel may be a normalized Gaussian kernel having a defined area based on a sensor spot size and a sample interval, the defined area of the normalized Gaussian kernel being maintained constant for the filtering of the data set.

According to another aspect of the current disclosure there is provided a method of providing data from a scanning sensor, wherein the sensor obtains data samples while performing a scan. The method comprising: identifying a set of predetermined spaced locations within the scanned data at which processed output data is required; and filtering the data obtained by the sensor for each of the predetermined spaced locations to obtain a set of filtered data samples corresponding to each of the spaced locations.

The filtering of the data may be performed only at the predetermined spaced locations. The predetermined locations may be predetermined grid points over a scanned area. The scanned area may be a surface of a wafer in a lithographic apparatus, the sensor may be a level sensor and the predetermined locations at which the data is processed may be predetermined wafer grid points.

The filtering of the data may utilize a kernel defined by a probability density function convoluted over samples in the data set to perform a weighted average of the samples, and wherein the shape of the kernel changes in response to variations in the spacing of the data samples.

The filtering of the data may comprise a tandem filter applied to the data prior to convolution of the kernel over samples in the data set. The tandem filter may comprise a sample averaging filter.

According to another aspect of the current disclosure there is provided a computer readable medium containing program instructions for causing a computer to perform a method according to the invention.

According to another aspect of the current disclosure there is provided a lithographic apparatus for performing metrology in a wafer forming process. The apparatus comprises: a scanning sensor configured to obtain a set of data samples of measurements across a surface of the wafer; a controller configured to control the scanning of the sensor such that a sample interval between successive samples is variable; and a processor configured to filter the data, wherein a kernel defined by a probability density function is convoluted over samples in the data set to perform a weighted average of the samples at a plurality of positions across the data set, and wherein a first order regression is applied to the filtered data to provide a processed data output.

The processor configured to filter the data may be further configured to apply a tandem filter prior to convolution of the kernel defined by a probability function over samples in the data set.

### BRIEF DESCRIPTION OF THE DRAWINGS

Embodiments will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIGS. 4A and 4B are plan views showing how wafer level sensor scans may be deployed;

FIG. 5 illustrates graphically a data filtering process for use in embodiments of the invention;

FIG. 6 is an illustration of a Gaussian kernel employed in a data filtering process;

FIGS. 7A, 7B and 7C are graphical illustrations showing how a Gaussian kernel for filtering scanned data varies across a scan for different scanning/filtering procedures;

FIGS. 8A and 8B are graphical illustrations showing edge effects for different Gaussian filter procedures applied to a scanned data set;

FIGS. 9A and 9B are block diagrams of two different procedures for processing a scanned set of data;

FIG. 10 is a graphical illustration showing data filtering kernel implementations for obtaining a grid-location Z-map.

FIG. 11 is a flow diagram showing the steps in a further data processing method in accordance with the present disclosure.

FIG. 12 is a block diagram of a procedure for processing a scanned set of data.

FIG. 13 is a flow diagram showing the steps in a further data processing method in accordance with the present disclosure.

### DETAILED DESCRIPTION

In the present document, the terms “radiation” and “beam” are used to encompass all types of electromagnetic radiation and particle radiation, including ultraviolet radiation (e.g. with a wavelength of 365, 248, 193, 157 or 126 nm), EUV (extreme ultra-violet radiation, e.g. having a wavelength in the range of about 5-100 nm), X-ray radiation, electron beam radiation and other particle radiation.

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

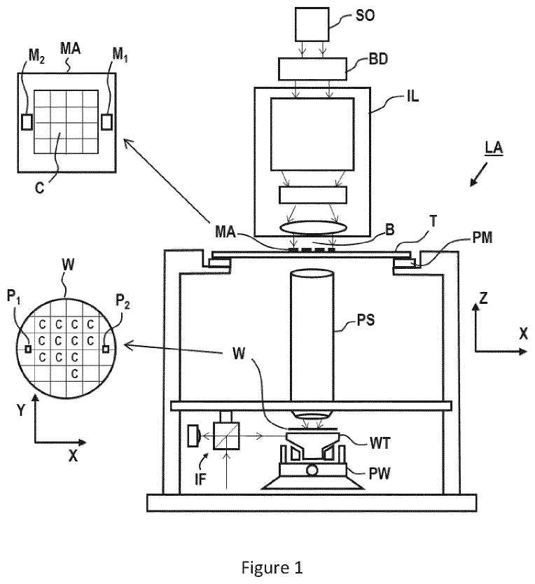

FIG. 1 schematically depicts a lithographic apparatus LA. The lithographic apparatus LA includes an illumination system (also referred to as illuminator) IL configured to condition a radiation beam B (e.g., UV radiation, DUV radiation, EUV radiation or X-ray radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, diffractive, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, diffractive, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference in its entirety.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT may be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

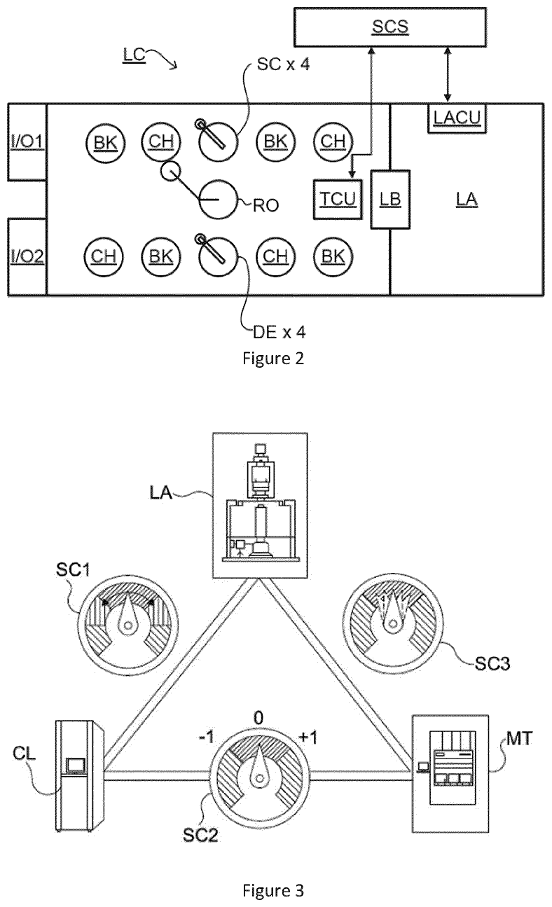

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, may be under the control of a track control unit TCU that in itself may be controlled by a supervisory control system SCS, which may also control the lithographic apparatus LA, e.g. via lithography control unit LACU.

In lithographic processes, it is desirable frequently to make measurements of the structures created, e.g., for process control and verification. Tools to make such measurement may be called metrology tools MT. Different types of metrology tools MT for making such measurements are known, including scanning electron microscopes or various forms of scatterometer metrology tools MT.

Before exposure of the substrate to transfer the pattern onto the substrate, a height level of the substrate may be determined and mapped. A resulting height map (wafer Z-map or WZM) of the substrate may be employed to position the substrate with respect to a projection system, for example.

In a conventional lithographic apparatus, the height map may be generated by sampling the height of the substrate at predetermined equidistant positions, e.g. positions lying on a rectangular measurement grid. A height level sensor and the substrate may be moved with respect to each other along a trajectory, which trajectory is selected along the predetermined positions. In the conventional lithographic apparatus, the measurement samples are taken while the substrate and the height level sensor move with respect to each other at a constant velocity. Thus, the height level sensor samples the equidistant measurement positions by sampling at a constant sampling rate. It is noted that in the measuring process the substrate or the height level sensor or both may move.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), shape of structures, etc. For this purpose, inspection tools and/or metrology tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

The patterning process in a lithographic apparatus LA may be one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—maybe within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). The resolution enhancement techniques may be arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

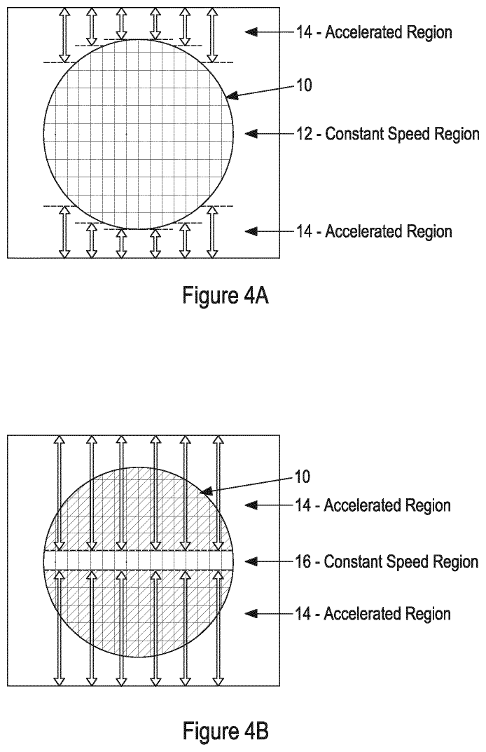

FIG. 4A illustrates, in a plan or top view, how a conventional level sensor (not shown) in a lithographic apparatus performs a scan over a wafer 10 in order to obtain a Wafer Z-Map (WZM). In the illustration, wafer 10 has a circular top surface, which is normal or standard for lithographic wafer processing, but the same principles discussed herein could also be applied to other shapes of wafer. The scan is performed at a constant speed over the wafer 10 so that the data samples acquired by the sensor are evenly spaced (in both time and space), but because the relative movement between the scanner and the wafer involves traversing back and forth there must be a deceleration at the end of each traverse before changing direction and then accelerating to the required speed over the wafer. As shown there are therefore regions 12 where the movement is at constant speed and regions 14 of acceleration/deceleration.

The Raw data measured by the Level Sensor (LS) undergoes post-processing to construct the Wafer Z-Map (WZM). The post-processing is performed within the LS driver and consists of operational blocks in which both level sensor and position monitor (PM) signals are shaped and recombined to build the WZM. A critical component of the post-processing of data from the level sensor is a Low Pass Filter (LPF), which is used to attenuate all the content (e.g. electronic noise) that corrupts the actual Z-height signal used to outline the topography on the wafer. Currently known systems operate in the frequency (Fourier) domain and require the raw LS data samples to be equi-spaced, a condition that is achieved only with a constant speed scan (or spatially variable sampling rate).

FIG. 4B illustrates an improvement to the above, as discussed in U.S. Pat. No. 7,227,614 B2, in which only a relatively narrow strip 16 across the middle of the wafer 10 is scanned at constant speed (although in some cases the “narrow strip” could have zero width), while other parts of the wafer are scanned at varying speed (accelerating or decelerating). The Z-map obtained is referred to as an Accelerated Wafer Z-Map (AWZM). However, although this leads to a faster scanning of the wafer, because the data samples are not equi-spaced, this gives rise to problems in the processing of the raw data from the level sensor, as discussed below.

With the Accelerated WZM (A-WZM), the raw data is acquired over an accelerated (non-constant) speed trajectory. As a consequence, the A-WZM data samples are non-equidistant in space, and they cannot easily be down-sampled and interpolated to provide correct Z-height values without severely impacting performance.

Another problem arises with the results obtained using known frequency domain filters, where the raw data gives a step-like Z-height at the border of the wafer due to the sharp or abrupt edge. The shape of the frequency response causes a ringing artifact (known as the Gibbs phenomenon), which leads to distorted data (significantly high and low data values) close to the wafer edge. A similar ringing artifact occurs where the wafer includes circuit features, such as step-like 3D NAND structures. One way that the ringing effect near the wafer edge is currently dealt with is by splitting the data into two sets, one inside and the other in a peripheral region outside a boundary known as the Focus Edge Clearance (FEC) defined at a set distance from the edge. Different data processing procedures are used for level sensor data obtained outside the FEC and the data obtained inside the FEC. The two data sets are filtered separately using two different methods. The frequency-based LPF is solely applied on the data inside the FEC, which needs to be artificially extended at the extremes to allow the so-called ringing effect to land outside the actual signal. The filter used outside the FEC filter can be a simple moving average filter. Once filtered, data inside and outside the FEC need to be recombined to deliver the full WZM. The different responses of the two filters at the FEC boundary has a direct impact on certain of the scanner optimization features that are used in application software products, including Leveling Options, which include an FEC optimizer to deliver the optimal FEC value at the customer site. Moreover, the application of two filters is impractical for design and maintenance reasons and adds significantly to the amount of data processing required.

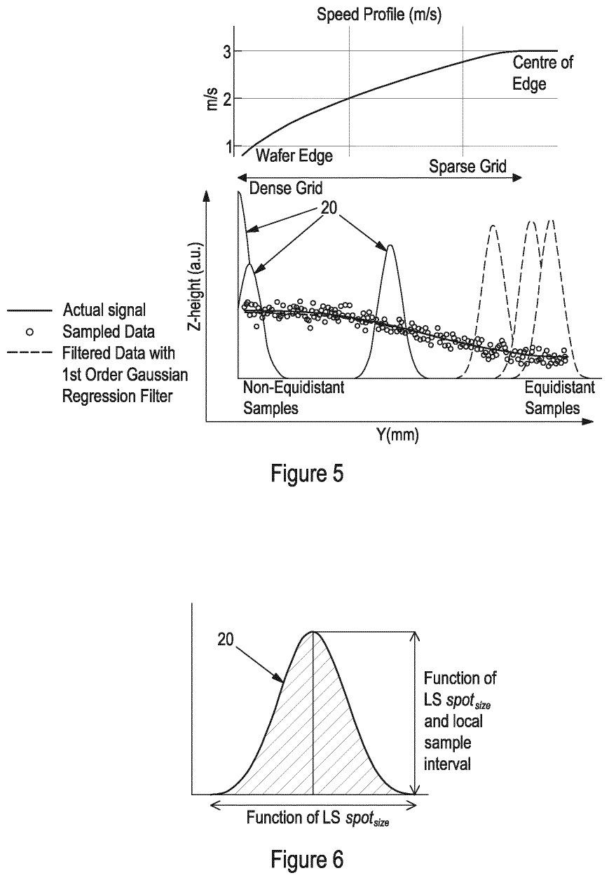

FIG. 5 illustrates graphically an approach to filtering of data that addresses the above problems. In the illustrated example, rather than filtering of the sensor data in the frequency domain (such as using a FFT filter), the approach is to filter the data in the space domain. Note that for a scanning sensor, such as the wafer Z-height sensor described above, time and space are essentially equivalent domains, with the spatial separation of successive data samples being determined by the time separation between samples and the speed of movement of the scanning sensor. However, the approach used here could also be applied to other types of data sample, for example if samples are taken from multiple stationary sensors distributed across an area (samples separated in the space domain), or data samples taken over time from a single sensor for some parameter such as temperature or pressure (time domain).

The upper graph of FIG. 5 shows a variable speed of movement (acceleration) of a scanning height sensor as it moves from the edge of a wafer towards a central region. The lower graph illustrates how filtering is applied at each of multiple locations across the wafer. Y is the direction of relative movement of a traverse of the scanner across the wafer and Z is the measured wafer height. At each location a kernel (or window) 20 is defined, which is based on a probability density function. The kernel represents a probability density function that is used to filter the data by applying a weighting based on each of the data samples, the weighting being determined by the probability density function and the data sample's position under the kernel. A first order regression is then applied to the weighted data samples.

As shown in FIG. 5, the kernel may be a Gaussian kernel defined by a Gaussian probability density function. However, others, such as Hann, Hamming or Kaiser functions, could also be used.

A discreet Gaussian distribution may be expressed in the form:

$${ω}_{N} ( {y}_{i} ) = \frac{1}{σ \sqrt{2 π}} {e}^{- \frac{{( {y}_{i} )}^{2}}{2 {σ}^{2}}}$$

$$σ = \frac{{spot}_{s i z e} on wafer}{2 π}$$

And for every sample zᵢ the weighted moving average is determined:

z_{filt,i}=z*ω

As shown in FIG. 6, the kernel 20 (in this example, Gaussian kernel) is determined with its base width being a function of the level sensor spot size, and its height a function of the level sensor spot size and the local sampling interval, the area under the curve is fixed during a convolution and normalized (equal to 1). It will be appreciated that filtering with the (Gaussian) kernel in this way, performing a moving weighted average of samples, means that the shape (height) of the kernel changes along the convolution as the spacing between data samples varies—e.g. as a result of a non-constant speed (acceleration/deceleration) of the scanning level sensor. This effect can be seen with the varying heights of the kernels at different Y locations. The slower scanning speed of the level sensor nearer to the wafer edge means that the data samples acquired are physically closer together/denser (in the Y-direction). As the scanner accelerates away from the wafer edge the separation between successive data samples becomes greater and the resulting heights of the kernels increases. Note that at less than one kernel's width from the edge of the wafer, the height of the kernel is also increased because there are fewer samples within the wafer, there being no samples beyond the wafer's edge. Also, as shown, the kernel is cropped in line with the wafer edge, removing any need for data extrapolation beyond the edge.

Applying a first order regression to the filtered data results in a further improvement of accuracy, particularly near the wafer edges. Regression solves an optimization problem by fitting a model curve: the goal is to obtain a best fit of the filtered data points. Without any regression (or 0^{th} order regression) no weights would be applied to the data points, and so they would have no influence in determining a best fit curve through them. When applying weights to the data points a model curve can be fitted using regression, which can be a line (first order, with 2 coefficients), a parabola (second order, with 3 coefficients) and so on. The higher the order, the more closely the curve follows the pattern of the points, but there is a greater chance that the best fit is being too heavily influenced by outlier points (i.e. noise). Keeping the order small (i.e. first order), provides a good compromise for the optimization.

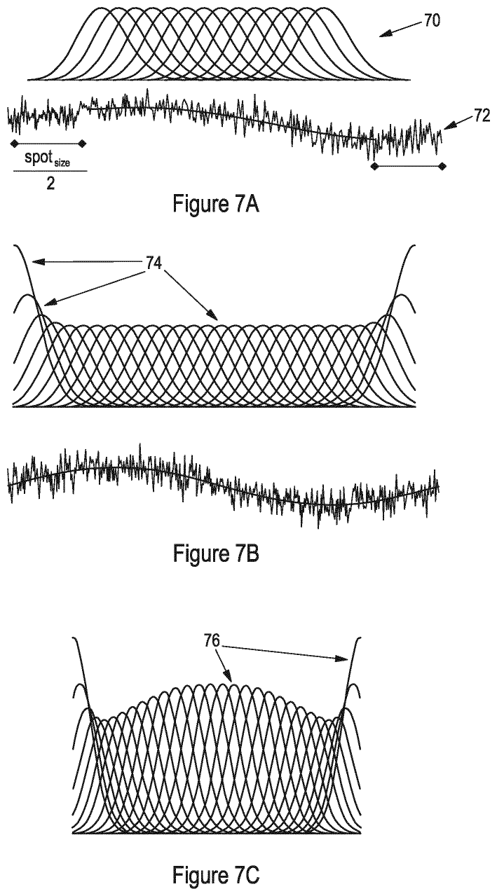

FIG. 7A provides a further illustration of a Gaussian filter applied to scanned data of a constant speed scan. The upper illustration 70 shows a constant height Gaussian kernel applied for filtering the data across the center of the wafer. The filtering is applied to the data obtained from the raw data in the trace 72 below. FIG. 7B illustrates a similar (constant speed) data scan, but in this case a normalized Gaussian kernel 74 is used for filtering across the full width of the wafer such that the kernel height increases towards the edges of the wafer and is cropped at the wafer edge (as described above). FIG. 7C illustrates a non-constant speed scan, in which the sensor accelerates away from one wafer edge towards the center and then decelerates towards the opposite wafer edge. Again the normalized Gaussian kernels 76 are higher at the wafer edges, but the kernels also increase in height towards the center, where the data is sparser.

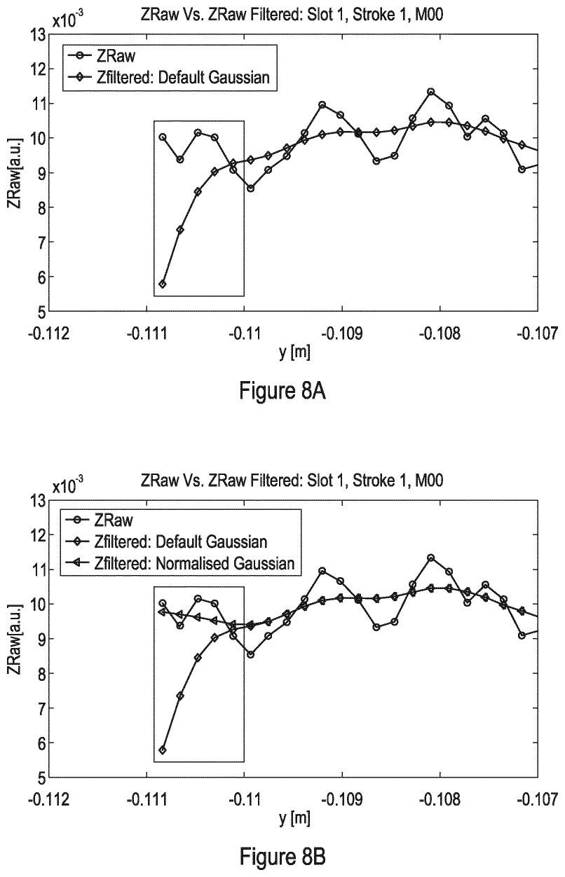

FIGS. 8A and 8B illustrate the effect that the filtering has on the data close to the wafer edge. FIG. 8A shows the effect of a fixed-height (i.e. not normalized) Gaussian kernel (as would arise in the constant speed scan of FIG. 7A extended to the edge of the wafer). As shown in FIG. 8A, the effect of the filter is to distort (i.e. make the filtered data inaccurate) close to the filter edge. However, as shown in FIG. 8B, if a Gaussian regression filter is used, with a normalized Gaussian kernel and a first order regression, then the filtered data is much more accurate right up to the wafer edge.

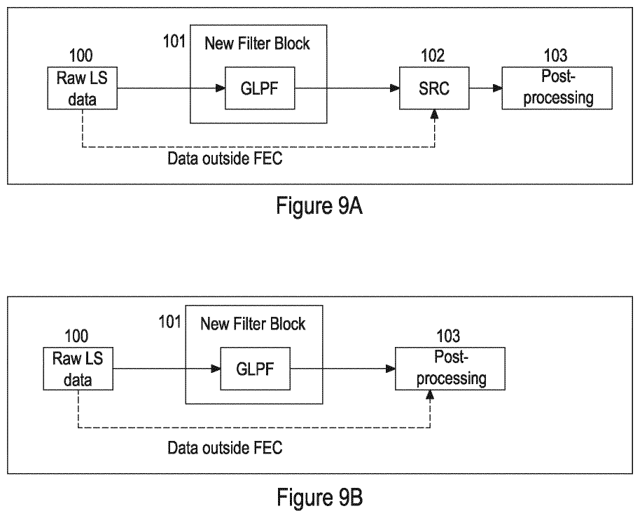

FIG. 9A is a block diagram illustrating the stages in processing of level sensor data. Raw level sensor data 100 is fed to a filter 101, which may be any suitable filter such as a frequency-based LPF or a Gaussian filter (GLPF) as discussed above. However, as explained above, data from outside the FEC is handled differently, as shown by the dashed line. The filtering block 101 is followed by a sample rate converter (SRC) block 102. The two separate sets of data, which have each been filtered separately using different filters, are recombined at the SRC 102, to interpolate and re-grid the signal from the original dense sampled grid to a fixed grid. Post-processing of data follows in block 103.

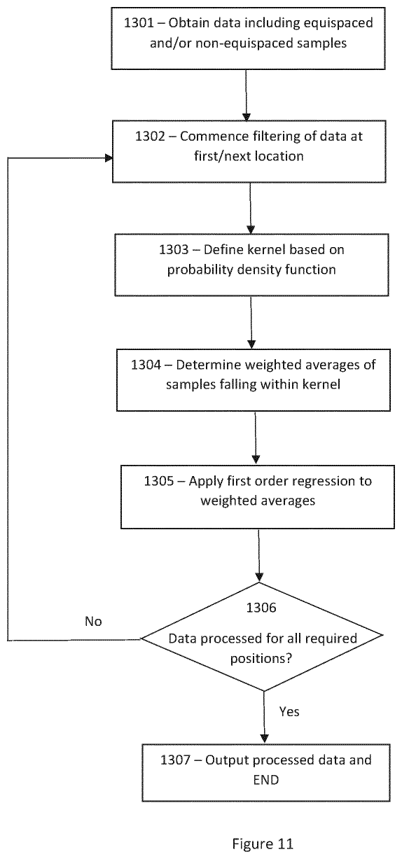

FIG. 9B shows the same process, but in this case without the separation and recombination of data from inside and outside the FEC at the SRC 102. The data for the entire wafer has been filtered using the same filter (e.g. Gaussian as described above). Accordingly there is no requirement for any recombination of the data at an SRC, which results in a significant reduction in the overall data processing. Moreover, the process illustrated in FIG. 11B can be used to directly provide WZM data at the prescribed grid points without interpolation. This is because it is normally only the WZM data at the specified grid points that is required by the other components of the wafer processing, and the rest of the data is simply not used. By only filtering and processing data at the required grid data points a substantial reduction in data processing can be achieved, as well as improved accuracy because no interpolation or extrapolation of data is required.

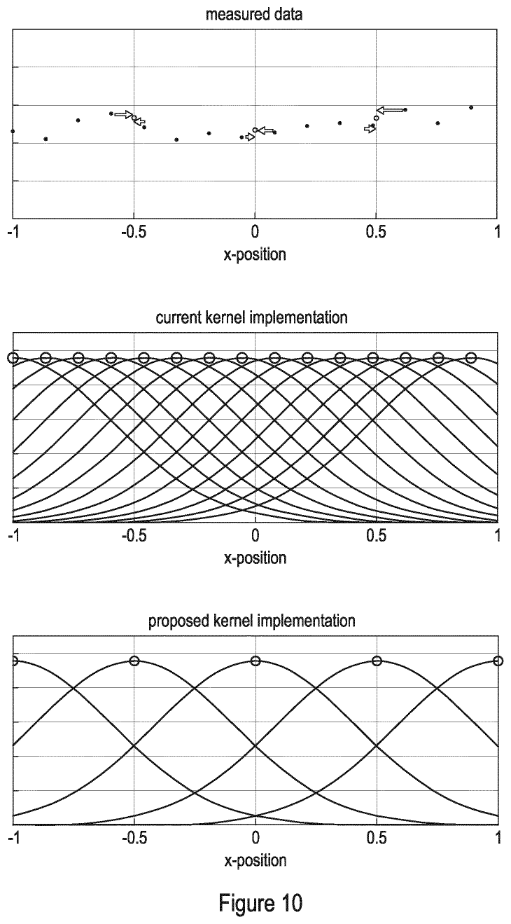

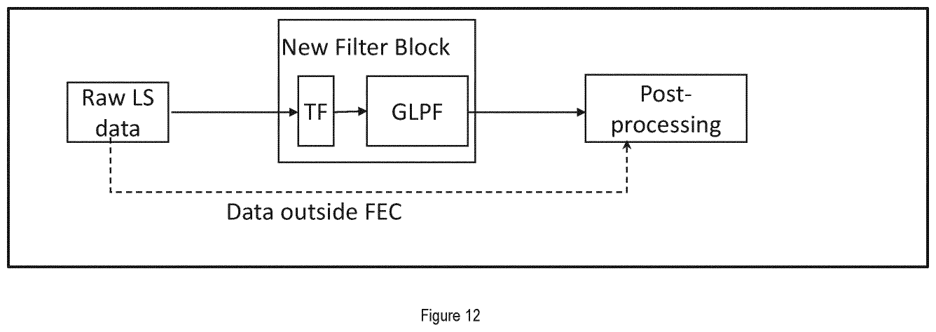

FIG. 10 demonstrates how the reduction in processing is achieved. The top graph shows a set of raw data obtained for a scan across a wafer. As the raw data samples may not fall at exactly the correct data location (y-position) required for a defined fixed grid, the data samples obtained for locations on each side of the required grid location are interpolated (or extrapolated for locations close to the wafer edge). The graph below illustrates the Gaussian kernels for each raw sample data location across the wafer (in a constant speed scan). However, the use of the kernel filtering methods described above allows the definition of a kernel at a precise location, which does not have to be the exact location of a raw data sample. This is because once the kernel has been defined, the data samples under the kernel are used to filter the data and obtain a filtered data value for the specified precise location. Therefore it is only necessary to perform the data filtering and subsequent processing at the specified fixed grid locations, as illustrated in the bottom graph in FIG. 12. Accordingly, the data processing system can be set up to only determine the kernels at the specified Sample Rate Converter (SRC) locations. This will result in the need for fewer kernels to be evaluated (making it faster) and without the need for interpolation, making it more accurate. Also, the total data processing becomes simpler because one block (SRC) can be removed. A consequence is that there is no longer high density filtered data. However, in most applications, particularly in the lithographic processes described above, there is no use of that data anyway.

The concept of only performing data filtering at specified grid locations, can also be applied to other types of filter, including the known Fourier LPF used with constant speed scans as described above. Filtering data only at the pre-specified locations not only reduces the amount of data processing required, it also improves accuracy by removing the need for interpolation.

FIG. 11 is a flow diagram illustrating process steps in a method of processing data. At step 1301 a set of data is obtained. For example this may be data from a scanning sensor, such as a level sensor. The data may comprise equi-spaced and/or non-equi-spaced data samples. At step 1302 filtering is commenced at the first (or next) location within the data set where it is determined that data processing is required. In some circumstances this may be at the location of every data sample or at a reduced number of data samples (e.g. every second or third or fourth . . . etc. sample). Alternatively the location may be a predetermined position within the data set, for example at set grid points across a scan. At step 1303 a kernel, based on a probability density function is determined. For example, as in the level sensor application described above the kernel may be a Gaussian kernel, based on a Gaussian function. At step 1304 weighted averages of the samples falling within the kernel are determined. Sat step 1305 a first order regression is applied to the weighted averages. At step 1306, if there are further positions at which processed output data is required, the procedure loops back to step 1302 to commence filtering for the next location. If, at step 1306 there are no more positions at which processed data is required the procedure continues to step 1307 where the processed data is output (or passed to the next stage, if additional processing is to be performed) and the procedure ends.

The data processing method may be further improved by implementing one or more additional filters in tandem. For example, high frequency content in raw data may result in data accuracy and reproducibility limitations as a result of limited attenuation filtering. It may therefore be desirable to improve pass band attenuation to increase accuracy, and/or it may be desirable to improve stop band attenuation to improve the reproducibility of results. Thus, a tandem filter may be added to the aforementioned data processing method, comprising for example sample averaging or subsampling of raw data samples. The tandem filter is applied prior to convolution of a kernel over the samples, which may be for example a Gaussian filter as described above.

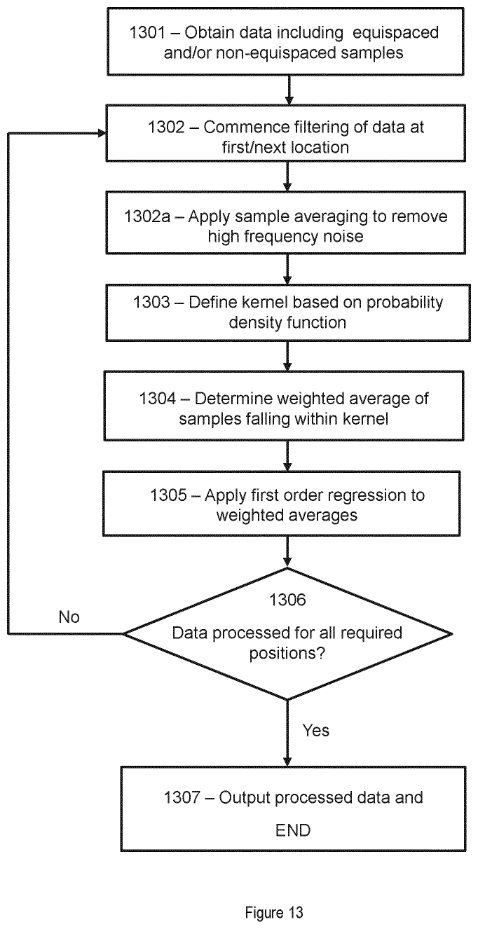

FIG. 12 is a block diagram illustrating the stages in processing level sensor data as in FIG. 9B, with an additional tandem filter TF as part of the New Filter Block 101. In the flow diagram of FIG. 13, the tandem filter is indicated at step 1302a, and in this embodiment (for the purposes of illustration only) is an exemplary sample averaging filter, which improves high frequency noise in the stop band. The subsequent filtering steps ensure maximum attenuation on the pass band and handle equi-spaced and/or non-equi-spaced data samples in line with the data processing method disclosed herein. It will be understood that the use of a tandem filter may not be limited to attenuating high frequency data, and may comprise any other filter optimized for a given purpose. One or more tandem filters each optimized to a particular purpose using known data filtering techniques may be incorporated with the data processing method of the present disclosure.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses:
1. A method of processing a data set comprising equispaced and/or non-equispaced data samples, the method comprising filtering of the data, wherein a kernel defined by a probability density function is convoluted over samples in the data set to perform a weighted average of the samples at a plurality of positions across the data set, and wherein a first order regression is applied to the filtered data to provide a processed data output.
2. The method of clause 1 wherein the filtering of the data comprises a tandem filter applied to the data prior to convolution of the kernel over samples in the data set.
3. The method of clause 2 wherein the tandem filter is a sample averaging filter.
4. The method of any preceding clause wherein the filtering is performed in a time and/or space domain.
5. The method of any preceding clause wherein the non-equispaced samples are temporally spaced and/or spatially spaced.
6. The method of any preceding clause wherein the data set comprises measurements obtained from a scanning sensor.
7. The method of clause 6 wherein the scanning sensor performs a scan across the surface of a wafer in a lithographic apparatus.
8. The method of clause 7 wherein the sensor is a level sensor.
9. The method of any of the preceding clauses wherein the shape of the kernel changes in response to variations in the spacing of the data samples.
10. The method of any of the preceding clauses wherein the kernel defined by a probability density function is a Gaussian kernel.
11. The method of clause 8 wherein the Gaussian kernel is a normalized Gaussian kernel having a defined area based on a sensor spot size and a sample interval, the defined area of the normalized Gaussian kernel being maintained constant for the filtering of the data set.
12. The method of any preceding clause wherein the filtering of the data samples comprises low-pass filtering and wherein a cut-off frequency above which data is filtered out varies according to variations in the spacing of the samples.
13. The method of clause 8, wherein the level sensor scans across the surface of the wafer at a variable speed so as to accelerate and decelerate across portions of the wafer surface while obtaining sensor data, and wherein the data output is used to provide an accelerated wafer Z-map (AWZ-Map) of the level of the wafer surface.
14. The method of any preceding clause, wherein the processed output data is required for a set of predetermined spaced locations, and wherein the processing of the data set is performed only at those predetermined locations.
15. The method of clause 14, wherein the predetermined locations are predetermined grid points over a scanned area.
16. The method of clause 14 or clause 15, wherein the scanned area is a surface of a wafer in a lithographic apparatus, the sensor is a level sensor and the predetermined locations at which the data is processed are predetermined wafer grid points.
17. A method of obtaining an accelerated wafer Z-map in a lithographic apparatus, the method comprising:
   using a scanning level sensor to obtain a set of data samples of level measurements across a surface of the wafer;
   filtering the data in a time and/or space domain using a kernel defined by a probability density function that is convoluted over samples in the data set to perform a weighted average of the samples at a plurality of positions across the data set; and
   applying a first order regression to the filtered data to obtain a level value for each of the plurality of positions.
18. The method of clause 17, wherein the set of data samples of level measurements is filtered by a tandem filter prior to being filtered in a time and/or space domain using a kernel defined by a probability density function.
19. The method of clause 18, wherein the tandem filter is sample averaging filter.
20. The method of any of clauses 17-19, wherein a sample interval between successive samples varies and wherein the shape of the kernel changes in response to variations in the sample interval.
21. The method of any of clauses 17-20, wherein the kernel defined by a probability density function is a Gaussian kernel.
22. The method of clause 21, wherein the Gaussian kernel is a normalized Gaussian kernel having a defined area based on a sensor spot size and a sample interval, the defined area of the normalized Gaussian kernel being maintained constant for the filtering of the data set.
23. A method of providing data from a scanning sensor, wherein the sensor obtains data samples while performing a scan, the method comprising:
   identifying a set of predetermined spaced locations within the scanned data at which processed output data is required; and
   filtering the data obtained by the sensor for each of the predetermined spaced locations to obtain a set of filtered data samples corresponding to each of the spaced locations.
24. The method of clause 23 wherein the filtering of the data is performed only at the predetermined spaced locations.
25. The method of clause 22 or clause 23, wherein the predetermined locations are predetermined grid points over a scanned area.
26. The method of clause 25, wherein the scanned area is a surface of a wafer in a lithographic apparatus, the sensor is a level sensor and the predetermined locations at which the data is processed are predetermined wafer grid points.
27. The method of any of clauses 23 to 26, wherein the filtering of the data utilizes a kernel defined by a probability density function convoluted over samples in the data set to perform a weighted average of the samples, and wherein the shape of the kernel changes in response to variations in the spacing of the data samples.
28. The method of clause 27, wherein the filtering of the data comprises a tandem filter applied to the data prior to convolution of the kernel over samples in the data set.
29. The method of clause 28, wherein the tandem filter comprises a sample averaging filter.
30. A computer readable medium containing program instructions for causing a computer to perform the method of any preceding clause.
31. A lithographic apparatus for performing metrology in a wafer forming process, the apparatus comprising:
   a scanning sensor configured to obtain a set of data samples of measurements across a surface of the wafer;
   a controller configured to control the scanning of the sensor such that a sample interval between successive samples is variable; and
   a processor configured to filter the data, wherein a kernel defined by a probability density function is convoluted over samples in the data set to perform a weighted average of the samples at a plurality of positions across the data set, and wherein a first order regression is applied to the filtered data to provide a processed data output.
32. The lithographic apparatus of clause 31, wherein the processor configured to filter the data is further configured to apply a tandem filter prior to convolution of the kernel defined by a probability function over samples in the data set.

1. A method of processing a data set comprising equispaced and/or non-equispaced data samples of measurements obtained from a scanning sensor, wherein the scanning sensor takes the measurements during a scan across a surface of a substrate in a lithographic apparatus, the method comprising filtering of the data, wherein a kernel defined by a probability density function is convoluted over samples in the data set to perform a weighted average of the samples at a plurality of positions across the data set, and wherein a first order regression is applied to the filtered data to provide a processed data output.

2.-7. (canceled)

8. The method of claim 1, wherein the sensor is a level sensor.

9.-12. (canceled)

13. The method of claim 2, wherein the level sensor takes the measurements during a scan across the surface of the substrate at a variable speed so as to accelerate and decelerate across portions of the substrate surface while obtaining sensor data, and wherein the data output is used to provide an accelerated substrate Z map (AWZ-Map) of the level of the substrate surface.

14. The method of claim 1, wherein the processed output data is required for a set of predetermined spaced locations, and wherein the processing of the data set is performed only at those predetermined locations.

15. The method of claim 14, wherein the predetermined locations are predetermined grid points over a scanned area.

16. The method of claim 14, wherein the scanned area is the surface of the substrate in the lithographic apparatus, the sensor is a level sensor and the predetermined locations at which the data is processed are predetermined substrate grid points.

17. A method of obtaining an accelerated substrate Z-map in a lithographic apparatus, the method comprising:
using a scanning level sensor to obtain a set of data samples of level measurements across a surface of the substrate;
filtering the data in a time and/or space domain using a kernel defined by a probability density function that is convoluted over samples in the data set to perform a weighted average of the samples at a plurality of positions across the data set; and
applying a first order regression to the filtered data to obtain a level value for each of the plurality of positions.

18. The method of claim 17, wherein the set of data samples of level measurements is filtered by a tandem filter prior to being filtered in a time and/or space domain using a kernel defined by a probability density function.

19. The method of claim 18, wherein the tandem filter is sample averaging filter.

20. The method of claim 17, wherein a sample interval between successive samples varies and wherein the shape of the kernel changes in response to variations in the sample interval.

21. The method of claim 17, wherein the kernel defined by a probability density function is a Gaussian kernel.

22. The method of claim 21, wherein the Gaussian kernel is a normalized Gaussian kernel having a defined area based on a sensor spot size and a sample interval, the defined area of the normalized Gaussian kernel being maintained constant for the filtering of the data set.

23. A method of providing data from a scanning sensor, wherein the sensor obtains data samples while performing a scan across a surface of a substrate in a lithographic apparatus, the method comprising:
identifying a set of predetermined spaced locations within the scanned data at which processed output data is required; and
filtering the data obtained by the sensor for each of the predetermined spaced locations to obtain a set of filtered data samples corresponding to each of the spaced locations.

24. The method of claim 23 wherein the filtering of the data is performed only at the predetermined spaced locations.

25.-29. (canceled)

30. A non-transitory computer-readable medium containing program instructions therein, the instructions, when executed by a computer system, configured to cause the computer system to perform at least the method of claim 23.

31. A lithographic apparatus for performing metrology in a substrate processing method, the apparatus comprising:
a scanning sensor configured to obtain a set of data samples of measurements across a surface of the substrate;
a controller configured to control scanning measurement by the sensor such that a sample interval between successive samples is variable; and
a processor configured to perform at least the method of claim 1.

32. The lithographic apparatus of claim 31, wherein the processor configured to filter the data is further configured to apply a tandem filter prior to convolution of the kernel defined by a probability function over samples in the data set.

33. A non-transitory computer-readable medium containing program instructions therein, the instructions, when executed by a computer system, configured to cause the computer system to perform at least the method of claim 1.

34. A non-transitory computer-readable medium containing program instructions therein, the instructions, when executed by a computer system, configured to cause the computer system to perform at least the method of claim 7.

35. The method of claim 22, wherein the predetermined locations are predetermined grid points over a scanned area.
